(19) United States
(12) Patent Application Publication
(10) Pub. No.: US 2026/0190643 A1
(43) Pub. Date: Jul. 2, 2026

(54) LIGHT EMITTING DISPLAY APPARATUS

(71) Applicant: LG Display Co., Ltd., Seoul (KR)

(72) Inventor: JiYoung AHN, Paju-si (KR)

(73) Assignee: LG Display Co., Ltd., Seoul (KR)

(21) Appl. No.: 19/393,235

(22) Filed: Nov. 18, 2025

(30) Foreign Application Priority Data
Dec. 26, 2024 (KR) 10-2024-0197724

(51) Int. Cl. H10K 59/122; H10K 59/38; H10K 59/80

(52) U.S. Cl. CPC H10K 59/122; H10K 59/38; H10K 59/8792

(57) ABSTRACT

A light emitting display apparatus may include a substrate including subpixels arranged in a first direction, each of the plurality of subpixels including an emission area and a non-emission area, at least one thin film transistor in the non-emission area, at least one protective layer on the thin film transistor, and at least one color filter on the protective layer in at least some of the plurality of subpixels, each of the plurality of subpixels may include a pixel electrode, an emission layer, a common electrode, and a bank portion defining an opening area of the pixel electrode, and at least one subpixel may have at least a portion of a color filter of at least one other subpixel, which is adjacent to the at least one subpixel, extends in the first direction and overlaps the opening area of the pixel electrode of the at least one subpixel.

### CROSS-REFERENCE TO RELATED APPLICATION

This application claims the benefit of and priority to Korean Patent Application No. 10-2024-0197724, filed in Republic of Korea on Dec. 26, 2024, the entirety of which is incorporated herein by reference for all purposes.

### BACKGROUND

### Technical Field

The present disclosure relates to a light emitting display apparatus.

### Discussion of the Related Art

With the advancement of the information age, the demand for a display apparatus for displaying an image has increased in various forms. Therefore, various types of display apparatuses, such as a liquid crystal display (LCD) apparatus, an organic light emitting display (OLED) apparatus, an inorganic light emitting display apparatus, a micro light emitting diode (LED) display apparatus, and a quantum dot display (QD) apparatus, have been recently used.

Among display apparatuses, the organic light emitting display apparatus, the quantum dot display apparatus, the inorganic light emitting display apparatus, and the micro LED display apparatus are a self-luminance type light emitting display apparatus. Light emitting display apparatus have advantages over conventional liquid crystal display apparatus in terms of viewing angle and contrast ratio, and do not require a separate backlight, thereby enabling a lightweight and thin profile and offering favorable power consumption.

Such the light emitting display apparatus has primarily employed a polarizer on a display surface of a display panel to reduce external light reflection. However, when the light emitting display apparatus uses a polarizer, transmittance decreases, thereby reducing display panel efficiency and increasing power consumption.

### SUMMARY

Accordingly, embodiments of the present disclosure are directed to a light emitting display apparatus that substantially obviate one or more problems due to limitations and disadvantages of the related art.

An aspect of the present disclosure may provide a light emitting display apparatus capable of reducing reflectance, improving light efficiency, and enhancing reflected color and visual perception without using a polarizer.

An aspect of the present disclosure may provide a light emitting display apparatus capable of reducing reflectance, improving light efficiency, and enhancing reflected color and visual perception while minimizing or reducing additional mask processes.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a light emitting display apparatus may comprise a substrate including a plurality of subpixels arranged in a first direction, each of the plurality of subpixels including an emission area and a non-emission area, at least one thin film transistor disposed in the non-emission area on the substrate, at least one protective layer disposed on the at least one thin film transistor, and at least one color filter disposed on the at least one protective layer in at least some of the plurality of subpixels, wherein each of the plurality of subpixels may include a pixel electrode, an emission layer, a common electrode, and a bank portion defining an opening area of the pixel electrode, and at least one subpixel among the plurality of subpixels may be disposed such that at least a portion of a color filter of at least one other subpixel, which is adjacent to the at least one subpixel, extends in the first direction and overlaps the opening area of the pixel electrode of the at least one subpixel.

According to one or more embodiments of the present disclosure, a light emitting display apparatus capable of reducing reflectance, improving light efficiency, and enhancing reflected color and visual perception without using a polarizer may be provided.

According to one or more embodiments of the present disclosure, a light emitting display apparatus capable of reducing reflectance, improving light efficiency, and enhancing reflected color and visual perception while minimizing or reducing additional mask processes may be provided.

The light emitting display apparatus according to one or more embodiments of the present disclosure may simplify the manufacturing process by eliminating the need for a polarizer while minimizing or reducing additional mask processes. As a result, it is possible to reduce greenhouse gas emissions generated during manufacturing and achieve Environmental, Social, and Governance (ESG) benefits.

The effects of the present disclosure are not limited to the aforesaid, but other effects not described herein will be clearly understood by those skilled in the art from the following descriptions.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain various principles and examples of the disclosure.

FIG. 1 illustrates a light emitting display apparatus according to an example embodiment of the present disclosure.

FIG. 2 is a circuit diagram illustrating a subpixel of a light emitting display apparatus according to an example embodiment of the present disclosure.

FIG. 3 illustrates a pixel structure of a light emitting display apparatus according to an example embodiment of the present disclosure.

FIG. 4 illustrates a bank portion and a color filter of a pixel according to an example embodiment of the present disclosure.

FIG. 5 is a cross-sectional view taken along line I-I′ in FIG. 4 according to an example embodiment of the present disclosure.

FIG. 6 illustrates a bank portion and a color filter of a pixel according to an example embodiment of the present disclosure.

FIG. 7 is a cross-sectional view taken along line II-II′ in FIG. 6 according to an example embodiment of the present disclosure.

FIG. 8 illustrates a bank portion and a color filter of a pixel according to another example embodiment of the present disclosure.

FIG. 9 is a cross-sectional view taken along line III-III′ in FIG. 8 according to another example embodiment of the present disclosure.

FIG. 10 illustrates a bank portion and a color filter of a pixel according to another example embodiment of the present disclosure.

FIG. 11 is a cross-sectional view taken along line IV-IV′ in FIG. 10 according to another example embodiment of the present disclosure.

FIG. 12 illustrates a bank portion and a color filter of a pixel according to another example embodiment of the present disclosure.

FIG. 13 is a cross-sectional view taken along line V-V′ in FIG. 12 according to another example embodiment of the present disclosure.

FIG. 14 illustrates a bank portion and a color filter of a pixel according to another example embodiment of the present disclosure.

FIG. 15 is a cross-sectional view taken along line VI-VI′ in FIG. 14 according to another example embodiment of the present disclosure.

FIG. 16 illustrates a bank portion and a color filter of a pixel according to another example embodiment of the present disclosure.

FIG. 17 is a cross-sectional view taken along line VII-VII′ in FIG. 16 according to another example embodiment of the present disclosure.

FIG. 18 illustrates a bank portion and a color filter of a pixel according to another example embodiment of the present disclosure.

FIG. 19 is a cross-sectional view taken along line VIII-VIII′ in FIG. 18 according to another example embodiment of the present disclosure.

FIG. 20 illustrates a bank portion and a color filter of a pixel according to another example embodiment of the present disclosure.

FIG. 21 is a cross-sectional view taken along line IX-IX′ in FIG. 20 according to another example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through various example embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings, are merely examples. Thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

Where the term “comprise,” “have,” “include,” “contain,” “constitute,” “made of,” “formed of,” or the like is used with respect to one or more elements, one or more other elements may be added unless a more limiting term, such as “only” or the like, is used. The terms used in the present disclosure are merely used in order to describe example embodiments and are not intended to limit the scope of the present disclosure. The terms of a singular form may include plural forms, and vice versa, unless the context clearly indicates otherwise.

In construing an element, the element is construed as including an error region although there is no explicit description thereof.

In describing a positional relationship, for example, where the positional order is described as “on,” “above,” “below,” “beneath”, and “next,” the case of no contact therebetween may be included, unless a more limiting term like “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, where the temporal order is described as “after,” “subsequent,” “next,” and “before,” a case which is not continuous may be included, unless a more limiting term like “just” or “direct” is used.

It will be understood that, although the terms “first,” “second,” etc., may be used herein to describe various elements, these elements should not be limited by these terms. These terms are only used to refer to one element separately from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various embodiments of the present disclosure may be partially or entirely coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more aspects, the components of each apparatus according to various embodiments of the present disclosure may operatively be coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness. Thus, embodiments of the present disclosure are not limited to a scale, dimension, size, and thickness illustrated in the drawings.

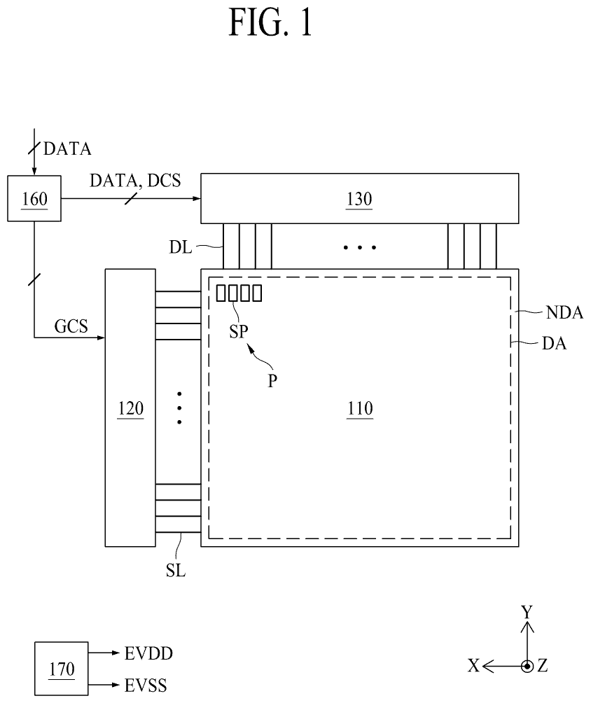

FIG. 1 illustrates a light emitting display apparatus according to an example embodiment of the present disclosure.

Hereinafter, an X-axis represents a direction parallel to a scan line (or a gate line), a Y-axis represents a direction parallel to a data line, and a Z-axis represents a height direction of the light emitting display apparatus.

A light emitting display apparatus according to an example embodiment of the present disclosure is implemented as an organic light emitting display apparatus, but may also be implemented as a liquid crystal display apparatus, a quantum dot lighting emitting diode display apparatus, or an electrophoretic display apparatus.

As shown in FIG. 1, the light emitting display apparatus according to an example embodiment of the present disclosure may include a display panel 110, a scan driver 120 (or a gate driver) embedded in the display panel 110, a data driver 130 connected to the display panel 110, a timing controller 160 controlling the scan driver 120 and the data driver 130, and a power circuit 170.

The display panel 110 includes a display area DA and a non-display area NDA surrounding the display area DA. The display panel 110 includes pixels P provided in the display area DA to display an image. Each of the pixels P may include a plurality of subpixels SP. The structure of the subpixel SP may be variously changed according to the type of the light emitting display apparatus. For example, the subpixels SP may be formed in a top emission type, a bottom emission type, or a dual emission type according to the structure. The subpixels SP indicate a unit capable of forming a color filter of a specific type or capable of emitting a color of itself without forming a color filter. The subpixels SP may have one or more other light-emitting areas according to light-emitting characteristics. For example, the plurality of subpixels SP may be arranged in a stripe type or a quad type, but embodiments of the present disclosure are not limited thereto. The color type, arrangement type, arrangement order, and the like of the subpixels SP may be configured in various forms according to the light-emitting characteristics, lifespan of the apparatus, spec of the apparatus, and the like.

The display panel 110 may include data lines DL and scan lines SL (or gate lines) connected to the subpixels SP. The data lines DL may be arranged to cross the scan lines SL. Each of the subpixels SP of the display panel 110 may be connected to any one of the data lines DL and any one of the scan lines SL. The data lines DL may supply a data voltage supplied from the data driver 130 to each of the subpixels SP. The scan lines SL may supply a scan signal supplied from the scan driver 120 to each of the subpixels SP.

Each of the subpixels SP is turned-on by the scan signal. When the data voltage of the data line DL is supplied to a gate electrode of a driving transistor, a light emitting element may emit light according to a drain-to-source current of the driving transistor. The scan driver 120 may receive a scan control signal GCS from the timing controller 160. The scan driver 120 may supply the scan signals or emission control signal to the scan lines SL by using the scan control signal GCS.

The scan driver 120 may be configured in a gate driver in panel GIP manner in the non-display area NDA outside one side or both sides of the display area DA. Alternatively, the scan driver 120 may be manufactured as a driving chip, mounted on a flexible film, and attached to the non-display area NDA outside one side or both sides of the display area DA in a tape automated bonding TAB manner.

The data driver 130 may receive digital video data DATA and a data control signal DCS from the timing controller 160. The data driver 130 converts the digital video data DATA into analog positive/negative data voltages by using the data control signal DCS and supplies the analog positive/negative data voltages to the data lines DL.

The timing controller 160 receives digital video data DATA and timing signals from a host system. The timing signals may include a vertical synchronization signal, a horizontal synchronization signal, a data enable signal, a dot clock, and the like. The vertical synchronization signal is a signal defining one frame period. The horizontal synchronization signal is a signal defining one horizontal period for supplying the data voltages to the pixels of one horizontal line of the display panel 110. The data enable signal defines a period in which valid data is input. The dot clock is a signal repeated at a predetermined short period.

The timing controller 160 may generate the data control signal DCS for controlling an operation timing of the data driver 130 and the scan control signal GCS for controlling an operation timing of the scan driver 120 based on the timing signals. The timing controller 160 may output the scan control signal GCS to the scan driver 120 to control the scan driver 120 and output the digital video data DATA and data control signal DCS to the data driver 130 to control the data driver 130.

The power circuit 170 may generate and supply a plurality of driving voltages for an operation of all circuit configurations of the light emitting display apparatus by using an input voltage. The power circuit 170 may generate a first power source voltage EVDD (or pixel power voltage), a second power supply voltage EVSS (or common power voltage) and an initialization voltage Vref (or reference voltage) and supply the generated voltages to the display panel 110. The power circuit 170 may generate and supply various driving voltages for operations of the scan driver 120, the data driver 130, and the timing controller 160.

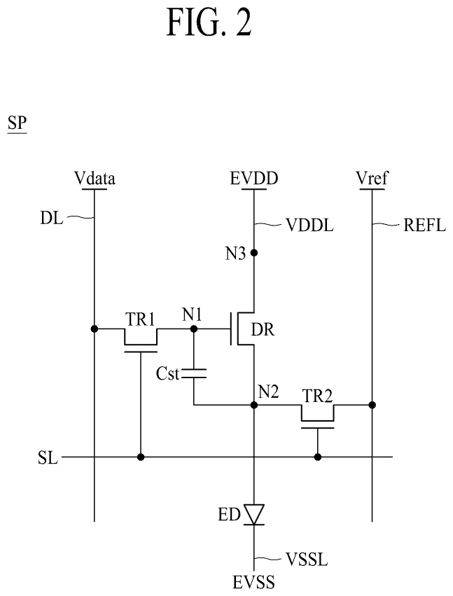

FIG. 2 is a circuit diagram illustrating a subpixel of a light emitting display apparatus according to an example embodiment of the present disclosure.

As shown in FIG. 2, each of pixels P includes the plurality of subpixels SP constituting a unit pixel. In each of the plurality of subpixels SP, there are a pixel circuit having 3T(Transistor)1C(Capacitor) including the driving transistor DR, the first switching transistor TR1, the second switching transistor TR2 and the storage capacitor Cst, and the light emitting device ED, but not limited thereto. Each subpixel SP may further include a compensation circuit. In this case, the subpixel SP may have various structures such as 3T2C, 4T1C, 4T2C, 5T1C, 5T2C, 6T1C, 6T2C, 7T1C, and 7T2C.

At least one thin film transistor DR, TR1 and TR2 of each subpixel SP may include a gate electrode, a source electrode, and a drain electrode. Since the source electrode and the drain electrode may be changed according to a voltage and a current direction applied to the gate electrode without being fixed, any one of the source electrode and the drain electrode may be represented as a first electrode, and the other may be represented as a second electrode. The at least one transistor DR, TR1, and TR2 may use at least one of polysilicon semiconductor, amorphous silicon semiconductor, and oxide semiconductor. The transistors DR, TR1, and TR2 may be P-type or N-type, or P-type and N-type may be interchangeably used.

The driving transistor DR corresponds to a transistor for driving the light emitting device ED, and the driving transistor DR includes the first node N1 to which the data voltage Vdata is applied, the second node N2 connected to a pixel electrode (first electrode or anode electrode) of the light emitting device ED, and the third node N3 connected to the first power line VDDL (or pixel power line) and supplied with the first power voltage EVDD (or pixel power voltage). For example, the driving transistor DR may generate a data current from the first power voltage EVDD supplied from the first power line VDDL and may supply the data current to the first electrode of the light emitting device ED.

The first switching transistor TR1 may serve to supply the data voltage Vdata supplied from the data line DL to the first node N1 of the driving transistor DR. The second switching transistor TR2 may serve to supply the reference voltage Vref supplied from the reference line REFL to the second node N2 of the driving transistor DR or may output a voltage of the second node N2 of the driving transistor DR. The storage capacitor Cst may be connected between the first node N1 and the second node N2 of the driving transistor DR. The storage capacitor Cst may serve to maintain the data voltage Vdata supplied to the driving transistor DR for one frame, but embodiments of the present disclosure are not limited thereto.

The light emitting device ED may include the pixel electrode (first electrode or anode electrode) connected to the second node N2 of the driving transistor DR, the common electrode (second electrode or cathode electrode) connected to the second power line VSSL. The light emitting device ED may emit light in response to a driving current generated by the driving transistor DR through an emission layer (or organic emission layer) between the first electrode and the second electrode. The pixel electrode of the light emitting device ED may be an independent electrode for each light emitting device, and the common electrode and the emission layer of the light-emitting device ED may be a common layer shared by the entire light emitting devices, but embodiments of the present disclosure are not limited thereto.

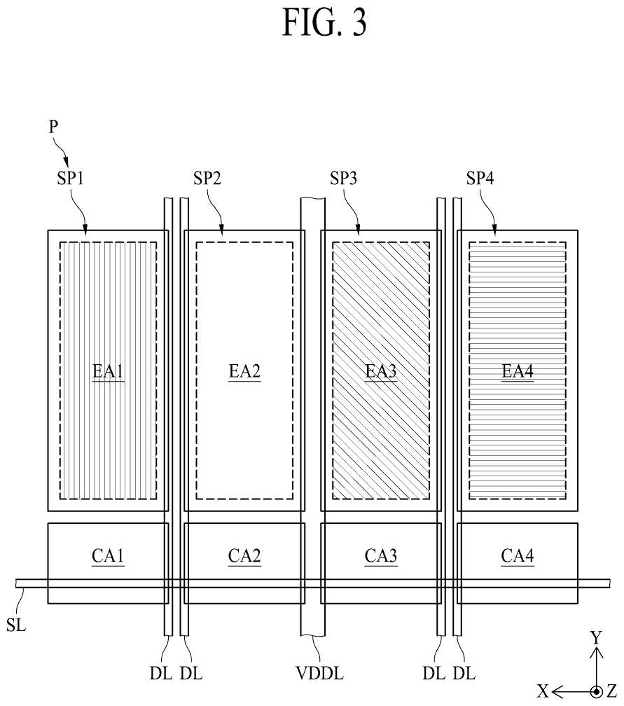

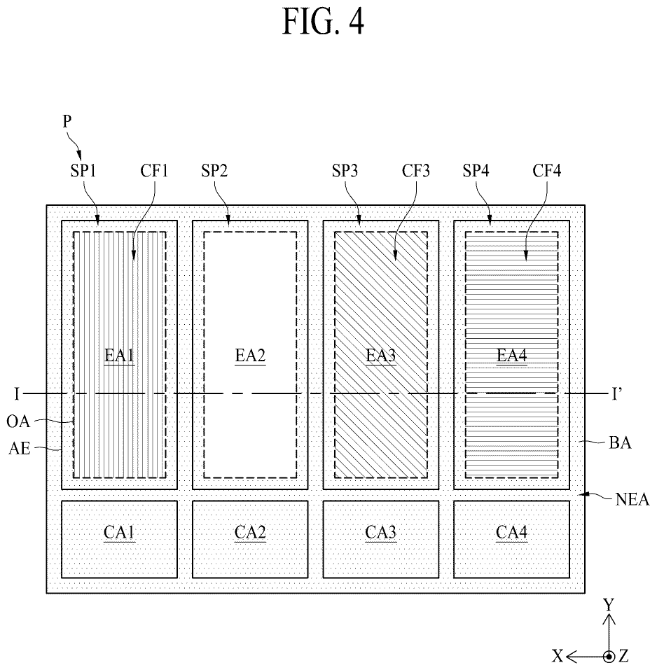

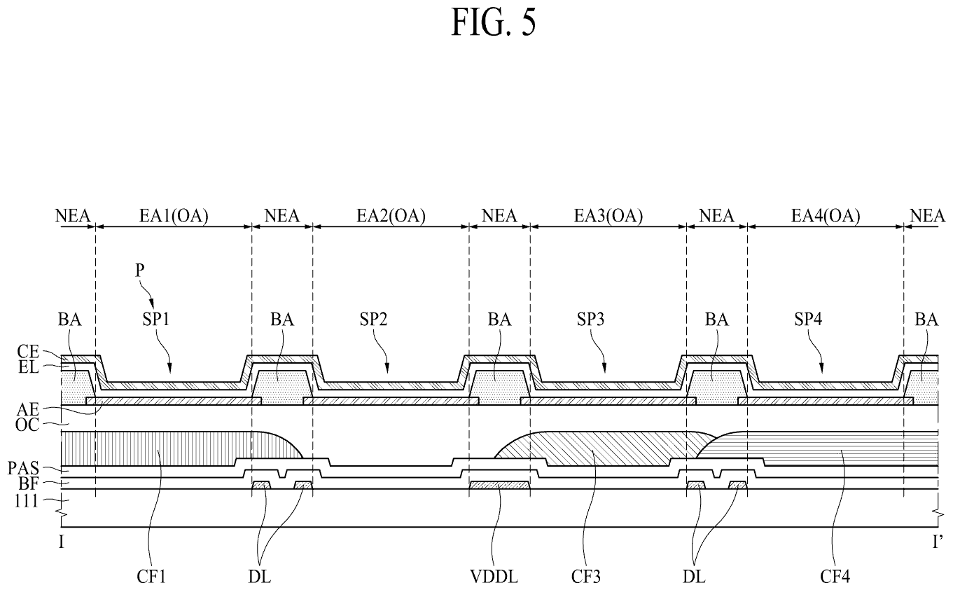

FIG. 3 illustrates a pixel structure of a light emitting display apparatus according to an example embodiment of the present disclosure. FIG. 4 illustrates a bank portion and a color filter of a pixel according to an example embodiment of the present disclosure. FIG. 5 is a cross-sectional view taken along line I-I′ in FIG. 4 according to an example embodiment of the present disclosure.

As shown in FIGS. 3 to 5, the light emitting display apparatus according to an embodiment of the present disclosure may include the pixel P, the data line DL, the scan line SL (or gate line), the first power line VDDL, the pixel circuits CA1, CA2, CA3 and CA4, the at least one color filter CF1, CF3 and CF4, and the bank portion BA.

The pixel P may include the plurality of subpixels SP1, SP2, SP3 and SP4. The plurality of subpixels SP1, SP2, SP3 and SP4 may include the first to fourth subpixels SP1, SP2, SP3 and SP4. The first to fourth subpixels SP1, SP2, SP3 and SP4 may be arranged in a first direction (or X-axis direction) or a second direction (or Y-axis direction). For example, the first to fourth subpixels SP1, SP2, SP3 and SP4 may be arranged adjacent to each other in the first direction (or X-axis direction). The first to fourth subpixels SP1, SP2, SP3 and SP4 may include emission areas EA1, EA2, EA3 and EA4 that emit light, and the non-emission area NEA.

The emission areas EA1, EA2, EA3 and EA4 may correspond to areas in the pixel P where light is emitted. The emission areas EA1, EA2, EA3 and EA4 may include first to fourth emission areas EA1, EA2, EA3 and EA4 that emit light of different colors. For example, the first to fourth emission areas EA1, EA2, EA3 and EA4 may overlap the opening areas OA of the pixel electrode AE (a first electrode or an anode electrode) defined by the bank portion BA.

The first to fourth emission areas EA1, EA2, EA3 and EA4 may overlap at least one color filter CF1, CF3 and CF4 corresponding to the first to fourth subpixels SP1, SP2, SP3 and SP4. For example, the first to fourth emission areas EA1, EA2, EA3 and EA4 may overlap the opening area OA of the pixel electrode AE and at least one color filter CF1, CF3 and CF4.

The first to fourth emission areas EA1, EA2, EA3 and EA4 may emit light of different colors through at least one color filter CF1, CF3 and CF4. For example, the at least one color filter CF1, CF3 and CF4 may emit light of different colors. For example, the at least one color filter CF1, CF3 and CF4 may be formed of an organic material that transmits light of different colors. The at least one color filter CF1, CF3 and CF4 may include the first color filter CF1 that transmits red light, the third color filter CF3 that transmits blue light, and the fourth color filter CF4 that transmits green light. For example, the first emission area EA1 of the first subpixel SP1 may emit red light through the first color filter CF1, the second emission area EA2 of the second subpixel SP2 may not be provided with a color filter and may emit white light, the third emission area EA3 of the third subpixel SP3 may emit blue light through the third color filter CF3, and the fourth emission area EA4 of the fourth subpixel SP4 may emit green light through the fourth color filter CF4, but embodiments of the present disclosure are not limited thereto.

The non-emission area NEA may include the data line DL, scan line SL (or gate line), the first power line VDDL, and the pixel circuits CA1, CA2, CA3 and CA4. The non-emission area NEA may overlap the bank portion BA. For example, the non-emission area NEA may be an area excluding the first to fourth emission areas EA1, EA2, EA3 and EA4 of the first to fourth subpixels SP1, SP2, SP3 and SP4.

The scan line SL extending in the first direction (or X-axis direction) may be disposed in the non-emission area NEA, and the data line DL and the first power line VDDL extending in the second direction (or Y-axis direction) intersecting the first direction may be disposed in the non-emission area NEA. Also, the second power line VSSL extending in the second direction may be disposed in the non-emission area NEA, but embodiments of the present disclosure are not limited thereto.

The pixel circuits CA1, CA2, CA3 and CA4 corresponding to each of the subpixels SP1, SP2, SP3 and SP4 may be disposed in the non-emission area NEA. For example, as shown in FIG. 2, each of the pixel circuits CA1, CA2, CA3 and CA4 may include the at least one thin film transistor DR, TR1 and TR2 and the storage capacitor Cst. The at least one thin film transistor DR, TR1 and TR2 may include the driving transistor DR, the first switching transistor TR1 and the second switching transistor TR2, but embodiments of the present disclosure are not limited thereto.

As shown in FIG. 5, the light emitting display apparatus according to an example embodiment of the present disclosure may include the substrate 111, the data line DL, the first power line VDDL, the buffer layer BF, the passivation layer PAS, the at least one color filter CF1, CF3 and CF4, the planarization layer OC, the pixel electrode AE, the organic emission layer EL, the common electrode CE, and the bank portion BA.

On the substrate 111, at least some of the at least one signal lines may be disposed. For example, on the substrate 111, the data line DL and the first power line VDDL may be disposed. Also, on the substrate 111, the reference line REFL and the second power line VSSL may be disposed, but embodiments of the present disclosure are not limited thereto. For example, at least one signal line disposed at the bottommost portion of the substrate 111 may be formed of the same material in the same layer as a light-shielding layer disposed in the pixel circuits CA1, CA2, CA3, and CA4. For example, the light-shielding layer may function to block external light incident on the active layer of the thin-film transistor. For example, the light-shielding layer may serve to block external light incident on an active layer of a thin film transistor. The light-shielding layer may be formed of a single layer or a multilayer of any one or more of molybdenum Mo, aluminum Al, chromium Cr, gold Au, titanium Ti, nickel Ni, neodymium Nd, and copper Cu, or an alloy thereof.

The buffer layer BF may be disposed on the substrate 111. The buffer layer BF may be configured to cover at least one signal line and a light-shielding layer disposed on the substrate 111. At least one protective layer and at least one thin film transistor may be disposed on the buffer layer BF. For example, the at least one protective layer may include the passivation layer PAS. The passivation layer PAS may be formed of a single layer or a multilayer that includes an inorganic insulating material such as silicon oxide SiO_{X}, silicon nitride SiN_{X}, or aluminum oxide Al₂O₃.

The at least one color filter CF1, CF3 and CF4 may be disposed on the passivation layer PAS. The at least one color filter CF1, CF3 and CF4 may be disposed to correspond to the first subpixel SP1, the third subpixel SP3, and the fourth subpixel SP4 among the first to fourth subpixels SP1, SP2, SP3 and SP4. A color filter may not be disposed in the second subpixel SP2 among the first to fourth subpixels SP1, SP2, SP3, and SP4. For example, the first color filter CF1 that converts white light emitted from the organic emission layer EL into red may be disposed in the first emission area EA1 of the first subpixel SP1. The second emission area EA2 of the second subpixel SP2 may emit white light as it is without a color filter. The third color filter CF3 that converts white light emitted from the organic emission layer EL into blue may be disposed in the third emission area EA3 of the third subpixel SP3. The fourth color filter CF4 that converts white light emitted from the organic emission layer EL into green may be disposed in the fourth emission area EA4 of the fourth subpixel SP4.

The planarization layer OC (or an overcoat layer) may be disposed on the passivation layer PAS and at least one color filter CF1, CF3 and CF4. The planarization layer OC may planarize step differences caused by at least one signal line, at least one thin film transistor, and at least one color filter CF1, CF3 and CF4 disposed on the substrate 111, and may be formed of an organic insulating material. For example, the planarization layer OC may be formed of an organic material such as acryl resin, epoxy resin, phenolic resin, polyamide resin, or polyimide resin, but embodiments of the present disclosure are not limited thereto.

The pixel electrode AE (first electrode or anode electrode), the organic emission layer EL, the common electrode CE (second electrode or cathode electrode), and the bank portion BA that constitute the light emitting device ED may be disposed on the planarization layer OC.

The pixel electrode AE may be disposed on the planarization layer OC. The pixel electrode AE may be patterned and disposed for each subpixel SP1, SP2, SP3 and SP4 on the planarization layer OC. The pixel electrode AE may be formed of a transparent metal material or a semi-transmissive metal material. For example, the pixel electrode AE may be formed of a transparent conductive material TCO such as indium tin oxide ITO or indium zinc oxide IZO that may transmit light. The pixel electrode AE may be formed of a semi-transmissive conductive material such as magnesium Mg, silver Ag, or an alloy of magnesium Mg and silver Ag. For example, the pixel electrode AE formed of the semi-transmissive metal material may improve light extraction efficiency by a micro cavity. The pixel electrode AE may be an anode electrode of the light emitting device ED. According to an embodiment of the present disclosure, the pixel electrode AE may further include a low-reflection metal layer. For example, the low-reflection metal layer may include a metal oxide or an alloy oxide. For example, the low-reflection metal layer may include copper oxide CuOx, nickel oxide NiOx, molybdenum oxide MoOx, or tungsten oxide WOx, but embodiments of the present disclosure are not limited thereto.

The bank portion BA may be disposed on the pixel electrode AE and the planarization layer OC. The bank portion BA may be disposed on the planarization layer OC to cover a portion of the edge of the pixel electrode AE. The bank portion BA may be configured to define the opening area OA of the pixel electrode AE. The opening area OA of the pixel electrode AE may correspond to the emission areas EA1, EA2, EA3 and EA4 of each subpixels SP1, SP2, SP3 and SP4. For example, the opening area OA of the pixel electrode AE exposed by the bank portion BA may be configured as the emission areas EA1, EA2, EA3 and EA4 that directly contact the emission layer EL and emit light.

The bank portion BA may be disposed in the non-emission area NEA of each subpixel SP1, SP2, SP3 and SP4. The bank portion BA may overlap the pixel circuits CA1, CA2, CA3 and CA4, and at least one signal line. For example, the bank portion BA may be formed of an organic layer such as acryl resin, epoxy resin, phenolic resin, polyamide resin, or polyimide resin. According to an embodiment of the present disclosure, the bank portion BA may be a black bank that includes at least one of a light-absorbing material or a black material. For example, the bank portion BA may include an insulating light-absorbing material such as black resin or graphite.

The organic emission layer EL may be disposed on the pixel electrode AE and the bank portion BA. The organic emission layer EL may include a hole transporting layer, an emission material layer, and an electron transporting layer. For example, when a voltage is applied to the pixel electrode AE and the common electrode CE, holes and electrons may move to the organic emission layer EL through the hole transporting layer and the electron transporting layer, respectively, and may be combined with each other in the organic emission layer EL to emit light. The organic emission layer EL may be a common layer commonly formed over the plurality of subpixels SP1, SP2, SP3 and SP4. For example, the organic emission layer EL may be a white emission layer that emits white light.

The common electrode CE may be disposed on the organic emission layer EL. The common electrode CE may be a common layer commonly formed over the plurality of subpixels SP1, SP2, SP3 and SP4. The common electrode CE may be disposed on the pixel electrode AE and the organic emission layer EL, which are in contact with each other, to constitute the light emitting device ED. For example, the common electrode CE may be formed of a metal material having high reflectance, such as a stacked structure (Ti/Al/Ti) of aluminum and titanium, a stacked structure (ITO/Al/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO. The Ag alloy may be an alloy of silver (Ag), palladium (Pd), copper (Cu) and the like. The MoTi alloy may be an alloy of molybdenum (Mo) and titanium (Ti). The common electrode CE may be a cathode electrode of the light emitting device ED. According to an embodiment of the present disclosure, the common electrode CE may further include a low-reflection metal layer. For example, the low-reflection metal layer may include a metal oxide or an alloy oxide. For instance, the low-reflection metal layer may include copper oxide (CuOx), nickel oxide (NiOx), molybdenum oxide (MoOx), or tungsten oxide (WOx), but embodiments of the present disclosure are not limited thereto.

According to an embodiment of the present disclosure, a transmittance control film may be further included on a rear surface of the substrate 111. For example, the transmittance control film may include at least one of a transparent film or an absorptive film, but embodiments of the present disclosure are not limited thereto.

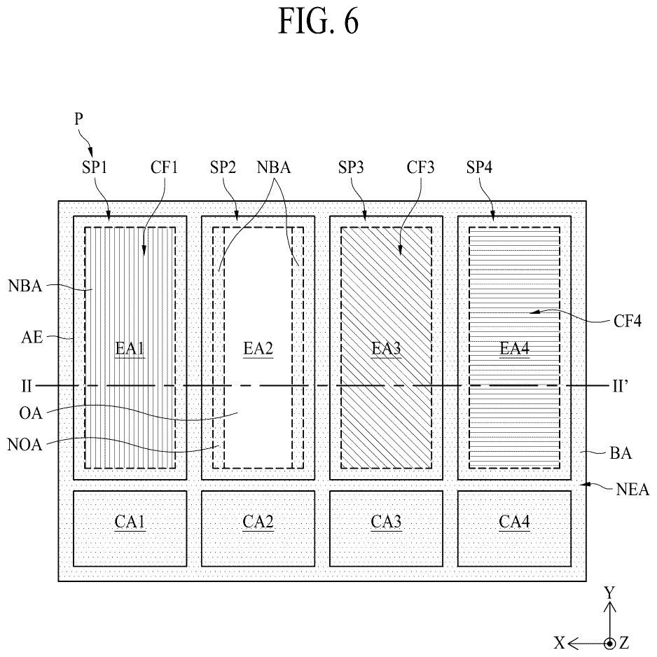

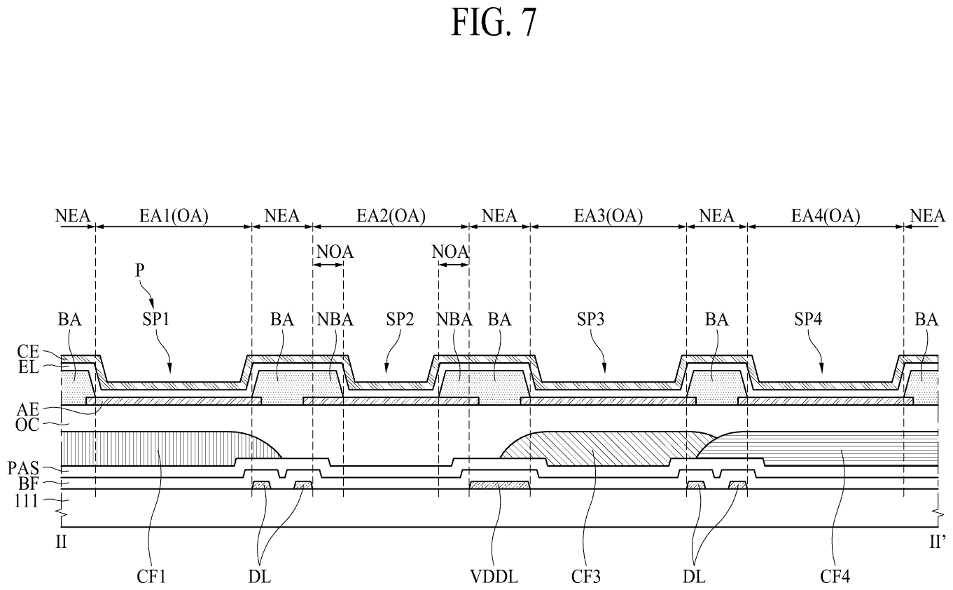

FIG. 6 illustrates a bank portion and a color filter of a pixel according to an example embodiment of the present disclosure. FIG. 7 is a cross-sectional view taken along line II-II′ in FIG. 6 according to an example embodiment of the present disclosure. FIGS. 6 and 7 illustrate embodiments of the present disclosure in which a configuration of the bank portion and the color filter is modified in the light emitting display apparatus described with reference to FIGS. 1 to 5. In the following description referring to FIGS. 6 and 7, the same reference numerals will be used for the same components, except for the modified configurations, and their redundant descriptions will be omitted or briefly described.

As shown in FIGS. 6 and 7, the light emitting display apparatus according to one embodiment of the present disclosure may be configured such that the bank portion BA disposed between a plurality of subpixels SP1, SP2, SP3 and SP4 extends toward a central portion of the pixel electrode AE in a first direction (or an X-axis direction) to define a non-opening area NOA of the pixel electrode AE. For example, the bank portion BA adjacent to the second subpixel SP2 may include a non-opening bank portion NBA disposed in the non-opening area NOA of the pixel electrode AE of the second subpixel SP2 in the first direction. For example, the non-opening bank portion NBA may be configured to extend from both left and right edge ends of the pixel electrode AE of the second subpixel SP2 toward the central portion of the pixel electrode AE in the first direction.

The non-opening bank portion NBA of the second subpixel SP2 may extend from the bank portion BA between the first subpixel SP1 and the second subpixel SP2 toward a central portion of the pixel electrode AE of the second subpixel SP2, and may also extend from the bank portion BA between the second subpixel SP2 and the third subpixel SP3 toward the central portion of the pixel electrode AE of the second subpixel SP2, thereby defining a non-opening area NOA of the pixel electrode AE. Accordingly, the emission area EA2 of the second subpixel SP2 may be configured to have a smaller area than the emission areas EA1, EA3, and EA4 of the first, third, and fourth subpixels SP1, SP3, and SP4. For example, the non-opening bank portion NBA of the second subpixel SP2 may overlap the pixel electrode AE of the second subpixel SP2. For example, the non-opening bank portion NBA may cover a portion of the pixel electrode AE, thereby reducing the aperture ratio of the light emitting portion. Also, the non-opening bank portion NBA may reduce a cell reflectance of the emission area by absorbing a portion of internal light that passes through the pixel electrode AE and is reflected again by the common electrode CE.

According to one embodiment of the present disclosure, the non-opening bank portion NBA may be configured to extend from the bank portions BA of the non-emission areas NEA at both left and right edges of the second subpixel SP2 toward a central portion of the pixel electrode AE of the second subpixel SP2, to define a non-opening area NOA of the pixel electrode AE, thereby optimizing an aperture ratio of the emission area EA2 of the second subpixel SP2 while minimizing or reducing additional mask processes. Accordingly, the light emitting display apparatus according to one embodiment of the present disclosure may reduce an increase in reflectance caused by the absence of a polarizer, and may improve light efficiency.

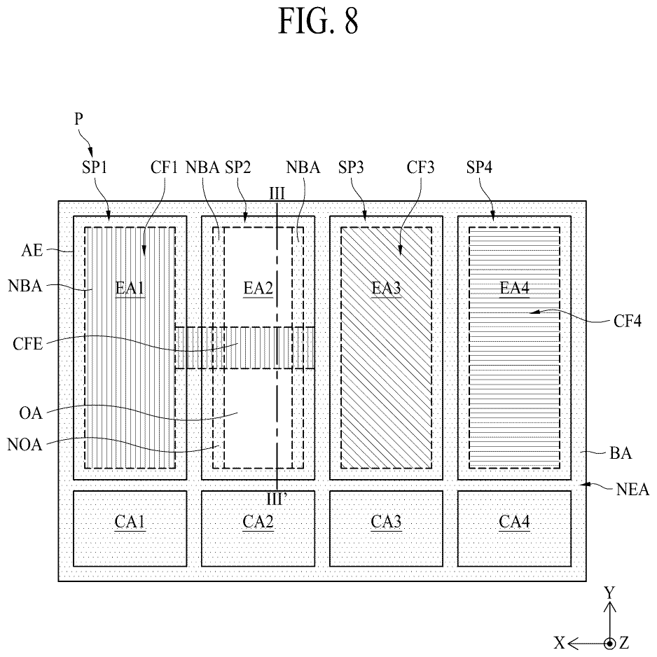

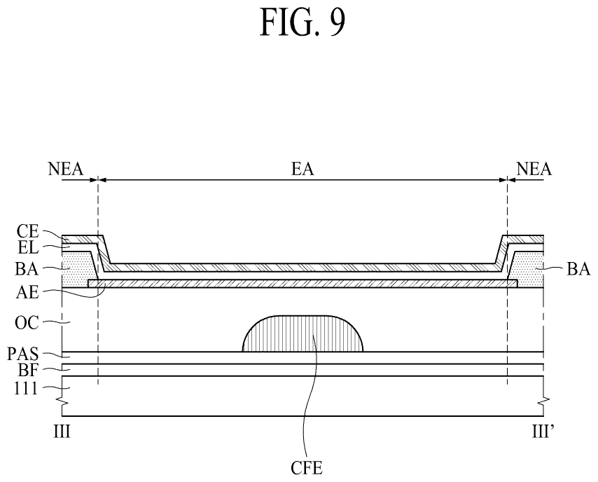

FIG. 8 illustrates a bank portion and a color filter of a pixel according to another example embodiment of the present disclosure. FIG. 9 is a cross-sectional view taken along line III-III′ in FIG. 8 according to another embodiment of the present disclosure. FIGS. 8 and 9 illustrate embodiments of the present disclosure in which a configuration of the bank portion and the color filter is modified in the light emitting display apparatus described with reference to FIGS. 1 to 7. In the following description referring to FIGS. 8 and 9, the same reference numerals will be used for the same components, except for the modified configurations, and their redundant descriptions will be omitted or briefly described.

As shown in FIGS. 8 and 9, the light emitting display apparatus according to another embodiment of the present disclosure may be configured such that the bank portion BA disposed between the plurality of the subpixels SP1, SP2, SP3 and SP4 extends toward a central portion of the pixel electrode AE in a second direction (or a Y-axis direction) intersecting a first direction (or an X-axis direction) to define the non-opening area NOA of the pixel electrode AE. For example, the bank portion BA adjacent to the second subpixel SP2 may include a non-opening bank portion NBA disposed in the non-opening area NOA of the pixel electrode AE of the second subpixel SP2 in the first direction.

The non-opening bank portion NBA of the second subpixel SP2 may extend from the bank portion BA between the first subpixel SP1 and the second subpixel SP2 toward a central portion of the pixel electrode AE of the second subpixel SP2, and may also extend from the bank portion BA between the second subpixel SP2 and the third subpixel SP3 toward the central portion of the pixel electrode AE of the second subpixel SP2, thereby defining a non-opening area NOA of the pixel electrode AE. Accordingly, the emission area EA2 of the second subpixel SP2 may be configured to have a smaller area than the emission areas EA1, EA3, and EA4 of the first, third, and fourth subpixels SP1, SP3, and SP4. For example, the non-opening bank portion NBA of the second subpixel SP2 may overlap the pixel electrode AE of the second subpixel SP2. For example, the non-opening bank portion NBA may cover a portion of the pixel electrode AE, thereby reducing the aperture ratio of the light emitting portion. Also, the non-opening bank portion NBA may reduce a cell reflectance of the emission area by absorbing a portion of internal light that passes through the pixel electrode AE and is reflected again by the common electrode CE.

According to another embodiment of the present disclosure, at least one of the subpixel SP2 may be configured such that at least a portion of a color filter CF1 and CF3 of at least one other subpixel SP1 and SP3, which is adjacent to the at least one subpixel SP2, extends in the first direction and overlaps the opening area OA of the pixel electrode AE. For example, at least a portion of the first color filter CF1 of the first subpixel SP1 may include a color filter extension portion CFE extending in the first direction. The color filter extension portion CFE of the first subpixel SP1 may be disposed to overlap the opening area OA of the pixel electrode AE of the second subpixel SP2. For example, the color filter extension portion CFE of the first subpixel SP1 may overlap the pixel electrode AE of the second subpixel SP2, and may also overlap the emission area EA2 of the second subpixel SP2. For example, the color filter extension portion CFE overlapping the emission area EA2 may absorb a portion of external light incident from outside before the light reaches the pixel electrode AE, thereby further reducing a cell reflectance of the emission portion.

The color filter extension portion CFE of the first subpixel SP1 may be disposed to overlap a central portion of the opening area OA of the pixel electrode AE of the second subpixel SP2 in a second direction (or a Y-axis direction) intersecting the first direction. For example, the color filter extension portion CFE may be configured such that the second subpixel SP2 has a reflectance equal to or lower than that of the other subpixels SP1, SP3 and SP4. For example, the color filter extension portion CFE may be configured to reduce a reflectance non-uniformity ratio of the second subpixel SP2. The reflectance non-uniformity ratio refers to a range in which the reflectance of a subpixel varies due to process deviations occurring during a manufacturing process of the light emitting display apparatus. For example, reducing the reflectance non-uniformity ratio may mean narrowing a variation range between a lower reflectance and a higher reflectance caused by process deviations, based on an average reflectance measured from a plurality of subpixels. According to another embodiment of the present disclosure, the color filter extension portion CFE having a lower reflectance than that of the second subpixel SP2 may be disposed at a central portion of the emission area EA2 of the second subpixel SP2. As a result, the influence of process deviations may be minimized, the average reflectance of the second subpixel SP2 may be optimized, and accordingly, the reflectance non-uniformity ratio caused by process deviations may be improved.

According to another embodiment of the present disclosure, the non-opening bank portion NBA may be configured to extend from the bank portions BA of the non-emission areas NEA at both left and right edges of the second subpixel SP2 toward a central portion of the pixel electrode AE of the second subpixel SP2 to define a non-opening area NOA of the pixel electrode AE, the first subpixels SP1, the third subpixel SP3, and the fourth subpixel SP4 may be configured not to include the non-opening bank portion NBA, and the color filter extension portion CFE of the first subpixel SP1 may be configured to overlap the emission area EA2 of the second subpixel SP2, thereby optimizing the aperture ratios and reflective color of the emission areas EA1, EA2, EA3 and EA4 while minimizing or reducing additional mask processes. Accordingly, the light emitting display apparatus according to another embodiment of the present disclosure may improve the reflectance non-uniformity ratio fluctuated by not using a polarizer, enhance light efficiency, and improve reflective color and visual perception.

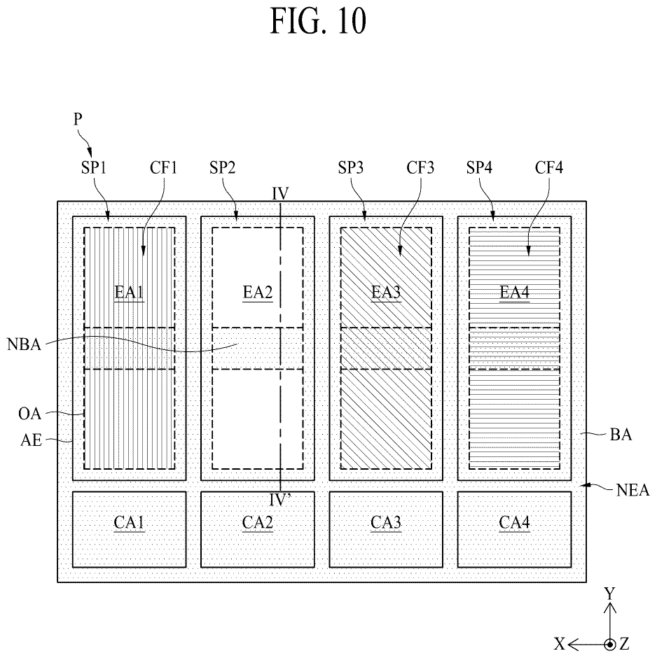

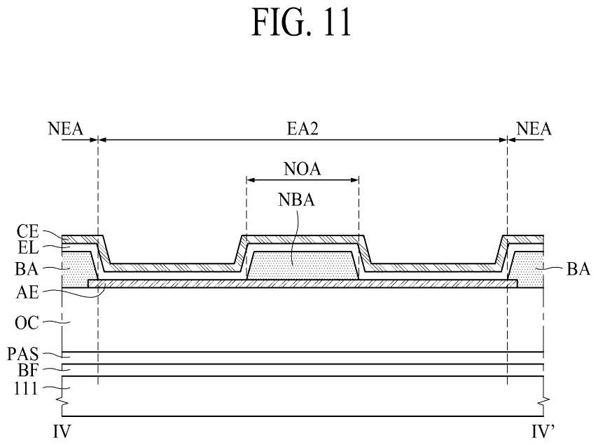

FIG. 10 illustrates a bank portion and a color filter of a pixel according to another example embodiment of the present disclosure. FIG. 11 is a cross-sectional view taken along line IV-IV′ in FIG. 10 according to another embodiment of the present disclosure. FIGS. 10 and 11 illustrate embodiments of the present disclosure in which a configuration of the bank portion and the color filter is modified in the light emitting display apparatus described with reference to FIGS. 1 to 9. In the following description referring to FIGS. 10 and 11, the same reference numerals will be used for the same components, except for the modified configurations, and their redundant descriptions will be omitted or briefly described.

As shown in FIGS. 10 and 11, the light emitting display apparatus according to another embodiment of the present disclosure may further include a non-opening bank portion NBA configured such that at least a portion of the bank portions BA of each of the plurality of subpixels SP1, SP2, SP3 and SP4 extends in a first direction (or an X-axis direction) to define a non-opening area NOA of the pixel electrode AE. For example, the non-opening bank portion NBA may be disposed between the pixel electrode AE and the organic emission layer EL.

The non-opening bank portion NBA may be disposed over the plurality of subpixels SP1, SP2, SP3 and SP4 in parallel in the first direction (or X-axis direction). For example, the non-opening bank portion NBA may be disposed to overlap with a central portion of the pixel electrode AE in a second direction (or Y-axis direction) that intersects the first direction. For example, the non-opening bank portion NBA may cover a portion of the pixel electrode AE, thereby reducing the aperture ratio of the light emitting portion. Also, the non-opening bank portion NBA may reduce a cell reflectance of the emission area by absorbing a portion of internal light that passes through the pixel electrode AE and is reflected again by the common electrode CE. Also, the non-opening bank portion NBA may be disposed in a central portion of the emission areas EA1, EA2, EA3 and EA4. As a result, the influence of process deviations may be minimized, the average reflectance of each of the subpixels SP1, SP2, SP3 and SP4 may be optimized, and accordingly, the reflectance non-uniformity ratio caused by process deviations may be improved.

According to another embodiment of the present disclosure, the non-opening bank portions NBA of the plurality of subpixels SP1, SP2, SP3 and SP4 may extend across the emission areas EA1, EA2, EA3 and EA4 of the subpixels SP1, SP2, SP3 and SP4 and be configured to define non-opening areas NOA of the respective pixel electrodes AE. As a result, the aperture ratio of the emission areas EA1, EA2, EA3, and EA4 may be optimized while minimizing or reducing the addition mask process. Accordingly, the light emitting display apparatus according to an embodiment of the present disclosure may reduce the reflectance increased by not using a polarizer, and may improve light efficiency.

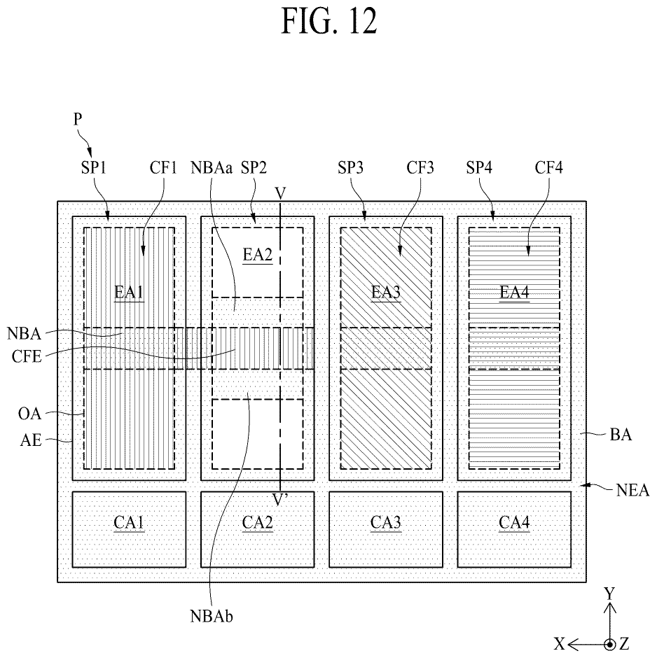

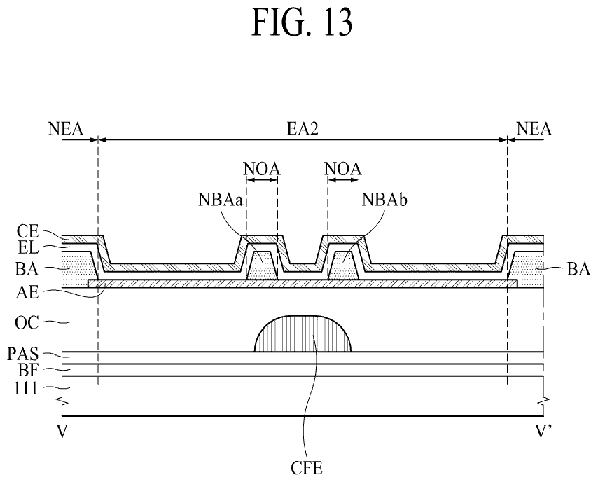

FIG. 12 illustrates a bank portion and a color filter of a pixel according to another example embodiment of the present disclosure. FIG. 13 is a cross-sectional view taken along line V-V′ in FIG. 12 according to another embodiment of the present disclosure. FIGS. 12 and 13 illustrate embodiments of the present disclosure in which a configuration of the bank portion and the color filter is modified in the light emitting display apparatus described with reference to FIGS. 1 to 11. In the following description referring to FIGS. 12 and 13, the same reference numerals will be used for the same components, except for the modified configurations, and their redundant descriptions will be omitted or briefly described.

As shown in FIGS. 12 and 13, the light emitting display apparatus according to another embodiment of the present disclosure may further include a non-opening bank portion NBA configured such that at least a portion of the bank portions BA of each of the plurality of subpixels SP1, SP2, SP3 and SP4 extends in a first direction (or an X-axis direction) to define a non-opening area NOA of the pixel electrode AE. For example, the non-opening bank portion NBA may be disposed between the pixel electrode AE and the organic emission layer EL.

The second subpixel SP2 among the plurality of subpixels SP1, SP2, SP3 and SP4 may be a white subpixel in which a color filter is not disposed, and the non-opening bank portion NBA of the second subpixel SP2 may be disposed to overlap at least a portion of a color filter extension portion CFE extended from the color filters CF1 and CF3 of at least adjacent subpixels SP1 and SP3.

The non-opening bank portion NBA of the second subpixel SP2 may include a first sub non-opening bank portion NBAa and a second sub non-opening bank portion NBAb that are spaced apart from each other with a color filter extension portion CFE therebetween in the second direction. For example, the first sub non-opening bank portion NBAa may be disposed to overlap one side of the color filter extension portion CFE in the second direction, and the second sub non-opening bank portion NBAb may be disposed to overlap the other side of the color filter extension portion CFE in the second direction. For example, the color filter extension portion CFE may be formed by extending from the color filter CF1 of the first subpixel SP1, and may be disposed to overlap a central portion of the opening area OA of the pixel electrode AE of the second subpixel SP2 in the second direction (or Y-axis direction). For example, the color filter extension portion CFE may be configured such that the second subpixel SP2 has a reflectance equal to or lower than that of the other subpixels SP1, SP3 and SP4. For example, the first and second sub non-opening bank portions NBAa and NBAb may be configured to have a line width equal to or smaller than a line width of the color filter extension portion CFE with respect to the second direction (or Y-axis direction). Also, the first and second sub non-opening bank portions NBAa and NBAb may be configured to cover edge portions of the color filter extension portion CFE, so that reflectance variation caused by a thickness difference between a central portion and edge portions of the color filter extension portion CFE may be minimized. According to another embodiment of the present disclosure, the color filter extension portion CFE having a lower reflectance than that of the second subpixel SP2 may be disposed at a central portion of the emission area EA2 of the second subpixel SP2, and the first and second sub non-opening bank portions NBAa and NBAb may be disposed to overlap one side and the other side of the color filter extension portion CFE. As a result, the influence of line width variations and process deviations of the color filter extension portion CFE may be minimized, thereby optimizing the average reflectance of the second subpixel SP2 and, accordingly, improving the reflectance non-uniformity ratio caused by process deviations.

According to another embodiment of the present disclosure, the non-opening bank portions NBA of the plurality of subpixels SP1, SP2, SP3 and SP4 may extend across the emission areas EA1, EA2, EA3 and EA4 of the subpixels SP1, SP2, SP3 and SP4 and define the non-emission areas NOA of the respective pixel electrodes AE. the color filter extension portion CFE having a lower reflectance than that of the second subpixel SP2 may be disposed in the emission area EA2 of the second subpixel SP2, and the first and second sub non-opening bank portions NBAa and NBAb may be disposed to overlap one side and the other side of the color filter extension portion CFE. For example, the first and second sub non-opening bank portions NBAa and NBAb may be configured to have a line width smaller than that of the color filter extension portion CFE in the second direction, and may reduce reflectance variation caused by a thickness difference between a central portion and edge portions of the color filter extension portion CFE. As a result, the aperture ratio of the emission areas EA1, EA2, EA3, and EA4 may be optimized while minimizing the addition of a mask process, the average reflectance of the second subpixel SP2 may be optimized, and accordingly, the reflectance non-uniformity ratio caused by process deviations may be improved. Accordingly, the light emitting display apparatus according to another embodiment of the present disclosure may reduce an increase in reflectance caused by the absence of a polarizer, improve the reflectance non-uniformity ratio, enhance light efficiency, and improve reflective color and visual perception.

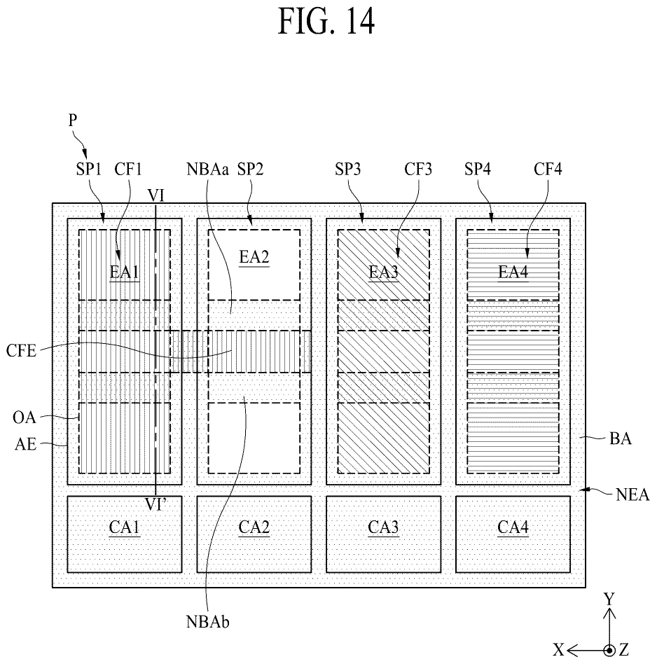

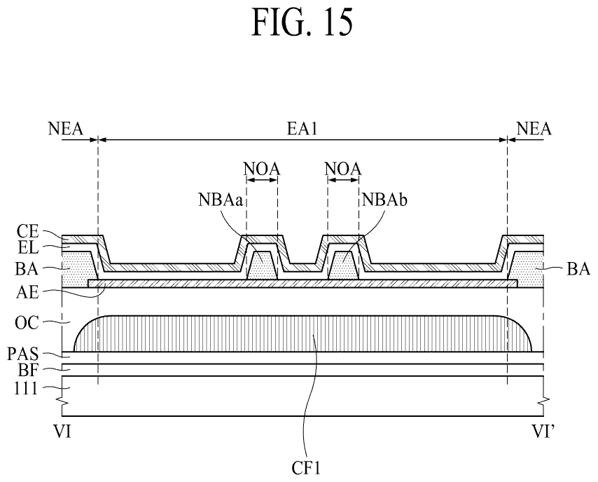

FIG. 14 illustrates a bank portion and a color filter of a pixel according to another example embodiment of the present disclosure. FIG. 15 is a cross-sectional view taken along line VI-VI′ in FIG. 14 according to another example embodiment of the present disclosure. FIGS. 14 and 15 illustrate embodiments of the present disclosure in which a configuration of the bank portion and the color filter is modified in the light emitting display apparatus described with reference to FIGS. 1 to 13. In the following description referring to FIGS. 14 and 15, the same reference numerals will be used for the same components, except for the modified configurations, and their redundant descriptions will be omitted or briefly described.

As shown in FIGS. 14 and 15, the light emitting display apparatus according to another embodiment of the present disclosure may further include a non-opening bank portion NBA configured such that at least a portion of the bank portions BA of each of the plurality of subpixels SP1, SP2, SP3 and SP4 extends in a first direction (or an X-axis direction) to define a non-opening area NOA of the pixel electrode AE. For example, the non-opening bank portion NBA may be disposed between the pixel electrode AE and the organic emission layer EL.

The non-opening bank portion NBA of each of the plurality of subpixels SP1, SP2, SP3 and SP4 may include a first sub non-opening bank portion NBAa and a second sub non-opening bank portion NBAb that are spaced apart from each other with a central portion of the pixel electrode AE therebetween in the second direction. For example, the first sub non-opening bank portion NBAa and the second sub non-opening bank portion NBAb may be disposed in parallel with each other in the first direction. For example, the first and second sub non-opening bank portions NBAa and NBAb may be disposed on the pixel electrodes AE of the plurality of subpixels SP1, SP2, SP3 and SP4, and may overlap at least one of the color filters CF1, CF3 and CF4. For example, as shown in FIG. 15, the first and second sub non-opening bank portions NBAa and NBAb may be disposed on the pixel electrode AE of the first subpixel SP1 and may overlap the color filter CF1 of the first subpixel SP1.

The second subpixel SP2 among the plurality of subpixels SP1, SP2, SP3 and SP4 may be a white subpixel in which a color filter is not disposed, and at least a portion of the first color filter CF1 of the first subpixel SP1 may be extended in the first direction and disposed to overlap the second subpixel SP2. The color filter extension portion CFE extended from the first color filter CF1 of the first subpixel SP1 may be disposed between the first sub non-opening bank portion NBAa and the second sub non-opening bank portion NBAb. For example, the color filter extension portion CFE may be formed by extending from the color filter CF1 of the first subpixel SP1 and may be disposed to overlap a central portion of the opening area OA of the pixel electrode AE of the second subpixel SP2 in the second direction (or Y-axis direction). For example, the color filter extension portion CFE may be configured such that the second subpixel SP2 has a reflectance equal to or lower than that of the other subpixels SP1, SP3 and SP4. For example, the first and second sub non-opening bank portions NBAa and NBAb may be configured to have a line width equal to or smaller than that of the color filter extension portion CFE in the second direction (or Y-axis direction). Also, the first and second sub non-opening bank portions NBAa and NBAb may be configured to cover edge portions of the color filter extension portion CFE, thereby minimizing reflectance variation caused by a thickness difference between the central portion and the edge portions of the color filter extension portion CFE. According to another embodiment of the present disclosure, the color filter extension portion CFE having a lower reflectance than that of the second subpixel SP2 may be disposed at the emission area EA2 of the second subpixel SP2, and the first and second sub non-opening bank portions NBAa and NBAb may be disposed to overlap one side and the other side of the color filter extension portion CFE. As a result, the influence of line width variations and process deviations of the color filter extension portion CFE may be minimized, and the reflectance variations caused by thickness differences between the central portion and edge portions of the color filter extension portion CFE may also be minimized, thereby optimizing the average reflectance of the second subpixel SP2 and, accordingly, improving the reflectance non-uniformity ratio caused by process deviations.

According to another embodiment of the present disclosure, the first and second sub non-opening bank portions NBAa and NBAb of the plurality of subpixels SP1, SP2, SP3 and SP4 may extend across the emission areas EA1, EA2, EA3 and EA4 of the subpixels SP1, SP2, SP3 and SP4, and define the plurality of non-emission areas NOA on respective pixel electrodes AE that are spaced apart from each other in the second direction and arranged in parallel in the first direction. The color filter extension portion CFE having a lower reflectance than that of the second subpixel SP2 may be disposed in the emission area EA2 of the second subpixel SP2, and the first and second sub non-opening bank portions NBAa and NBAb may be disposed to overlap one side and the other side of the color filter extension portion CFE. As a result, the aperture ratio of the emission areas EA1, EA2, EA3 and EA4 may be optimized while minimizing the addition of a mask process, the average reflectance of the second subpixel SP2 may be optimized, and accordingly, the reflectance non-uniformity ratio caused by process deviations may be improved. Accordingly, the light emitting display apparatus according to another embodiment of the present disclosure may reduce an increase in reflectance caused by the absence of a polarizer, improve the reflectance non-uniformity ratio, enhance light efficiency, and improve reflective color and visual perception.

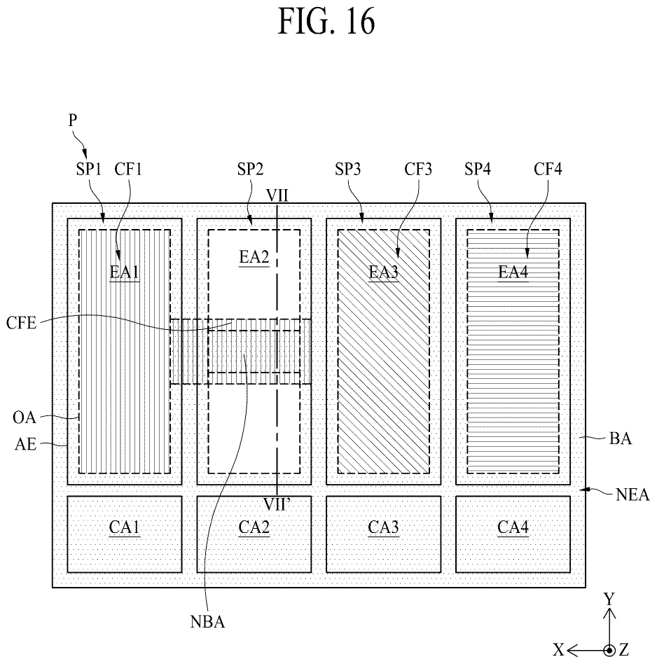

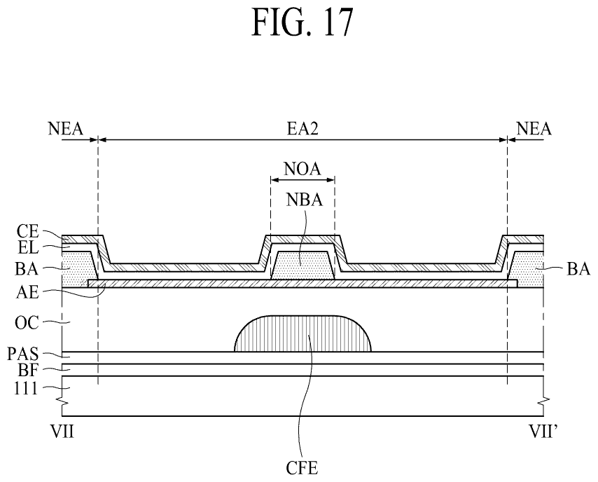

FIG. 16 illustrates a bank portion and a color filter of a pixel according to another example embodiment of the present disclosure. FIG. 17 is a cross-sectional view taken along line VII-VII′ in FIG. 16 according to another example embodiment of the present disclosure. FIGS. 16 and 17 illustrate embodiments of the present disclosure in which a configuration of the bank portion and the color filter is modified in the light emitting display apparatus described with reference to FIGS. 1 to 15. In the following description referring to FIGS. 16 and 17, the same reference numerals will be used for the same components, except for the modified configurations, and their redundant descriptions will be omitted or briefly described.

As shown in FIGS. 16 and 17, the light emitting display apparatus according to another embodiment of the present disclosure may further include a non-opening bank portion NBA in which at least a portion of the bank portion BA of the second subpixel SP2 extends in the first direction to define a non-opening area NOA of the pixel electrode AE.

The non-opening bank portion NBA may be disposed in the second subpixel SP2, and not in the first, third, and fourth subpixels SP1, SP3 and SP4. Accordingly, the emission area EA2 of the second subpixel SP2 may be configured to have a smaller area than the emission areas EA1, EA3 and EA4 of the other subpixels SP1, SP3 and SP4.

At least a portion of the first color filter CF1 of the first subpixel SP1 may be extended in the first direction and disposed to overlap a central portion of the pixel electrode AE of the second subpixel SP2. The color filter extension portion CFE extended from the first color filter CF1 may be disposed to overlap the non-opening bank portion NBA disposed in the second subpixel SP2. For example, the non-opening bank portion NBA of the second subpixel SP2 may be disposed to overlap a central portion of the color filter extension portion CFE of the first color filter CF1 in the second direction. For example, the color filter extension portion CFE may be formed by being extended from the color filter CF1 of the first subpixel SP1, and may be configured to overlap a central portion of the opening area OA of the pixel electrode AE of the second subpixel SP2 in the second direction (or Y-axis direction), and to have a width greater than that of the non-opening bank portion NBA of the second subpixel SP2. For example, the color filter extension portion CFE may be configured such that the second subpixel SP2 has a reflectance equal to or lower than that of the other subpixels SP1, SP3 and SP4. According to another embodiment of the present disclosure, the color filter extension portion CFE having a lower reflectance than that of the second subpixel SP2 may be disposed in the emission area EA2 of the second subpixel SP2, and the non-opening bank portion NBA may be disposed to overlap a central portion of the color filter extension portion CFE. As a result, the influence of line width variations and process deviations of the color filter extension portion CFE may be minimized, thereby optimizing the average reflectance of the second subpixel SP2 and, accordingly, improving the reflectance non-uniformity ratio caused by process deviations.

According to another embodiment of the present disclosure, the non-opening bank portion NBA of the second subpixel SP2 may extend across the emission area EA2 of the second subpixel SP2 and define the non-opening area NOA at a central portion of the pixel electrode AE of the second subpixel SP2. The color filter extension portion CFE having a lower reflectance than that of the second subpixel SP2 may be disposed in the emission area EA2 of the second subpixel SP2, and the non-opening bank portion NBA may be disposed to overlap a central portion of the color filter extension portion CFE. As a result, the aperture ratios of the emission areas EA1, EA2, EA3 and EA4 may be optimized while minimizing the addition of a mask process, the average reflectance of the second subpixel SP2 may be optimized, and accordingly, the reflectance non-uniformity ratio caused by process deviations may be improved. Accordingly, the light emitting display apparatus according to another embodiment of the present disclosure may reduce an increase in reflectance caused by the absence of a polarizer, improve the reflectance non-uniformity ratio, enhance light efficiency, and improve reflective color and visual perception.

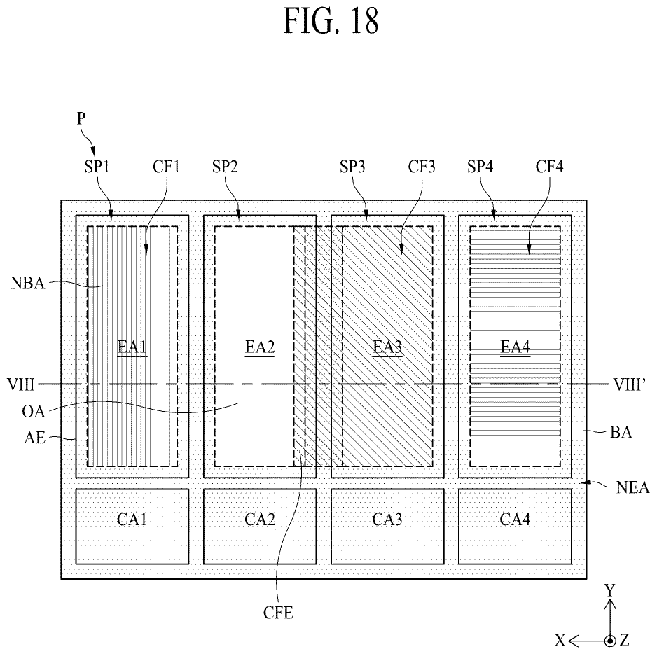

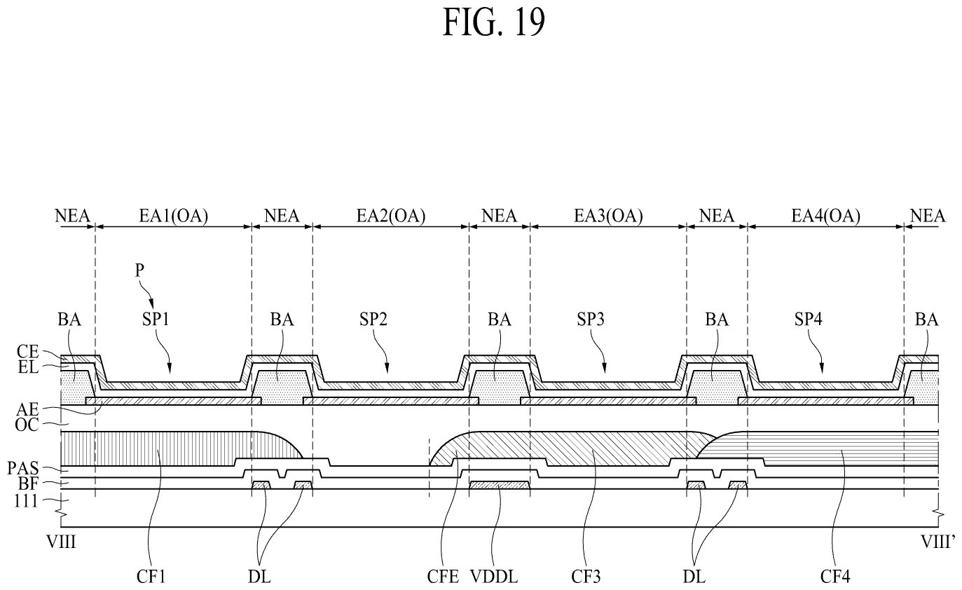

FIG. 18 illustrates a bank portion and a color filter of a pixel according to another example embodiment of the present disclosure. FIG. 19 is a cross-sectional view taken along line VIII-VIII′ in FIG. 18 according to another example embodiment of the present disclosure. FIGS. 18 and 19 illustrate embodiments of the present disclosure in which a configuration of the bank portion and the color filter is modified in the light emitting display apparatus described with reference to FIGS. 1 to 17. In the following description referring to FIGS. 18 and 19, the same reference numerals will be used for the same components, except for the modified configurations, and their redundant descriptions will be omitted or briefly described.

As shown in FIGS. 18 and 19, at least one subpixel SP2 of the light emitting display apparatus according to another embodiment of the present disclosure may be configured such that the color filter CF1 and CF3 of at least one other subpixel SP1 and SP3, which is adjacent to the at least one subpixel SP2, extends in the first direction and overlaps the opening area OA of the pixel electrode AE. For example, the third color filter CF3 of the third subpixel SP3 may be extended in a first direction and disposed to overlap the opening area OA of the pixel electrode AE of the second subpixel SP2. The color filter extension portion CFE extended from the third color filter CF3 may be disposed to overlap the non-opening area NOA and the opening area OA of the second subpixel SP2. For example, the color filter extension portion CFE may be formed by extending from the color filter CF3 of the third subpixel SP3, and may be configured to overlap a right edge of the pixel electrode AE of the second subpixel SP2. For example, the color filter extension portion CFE may be configured such that the second subpixel SP2 has a reflectance equal to or lower than that of the other subpixels SP1, SP3 and SP4. According to another embodiment of the present disclosure, the color filter extension portion CFE having a lower reflectance than that of the second subpixel SP2 may be disposed in the emission area EA2 of the second subpixel SP2. As a result, the influence of line width variations and process deviations of the color filter extension portion CFE may be minimized, thereby optimizing the average reflectance of the second subpixel SP2 and, accordingly, improving the reflectance non-uniformity ratio caused by process deviations.

According to another embodiment of the present disclosure, the color filter extension portion CFE having a lower reflectance than that of the second subpixel SP2 may be disposed in the emission area EA2 of the second subpixel SP2, and the color filter extension portion CFE may be disposed to overlap the right edge of the pixel electrode AE of the second subpixel SP2. As a result, the aperture ratios of the emission areas EA1, EA2, EA3 and EA4 may be optimized while minimizing the addition of a mask process, the average reflectance of the second subpixel SP2 may be optimized, and accordingly, the reflectance non-uniformity ratio caused by process deviations may be improved. Accordingly, the light emitting display apparatus according to another embodiment of the present disclosure may reduce the increase in reflectance caused by the absence of a polarizer, improve the reflectance non-uniformity ratio, enhance light efficiency, and improve reflective color and visual perception.

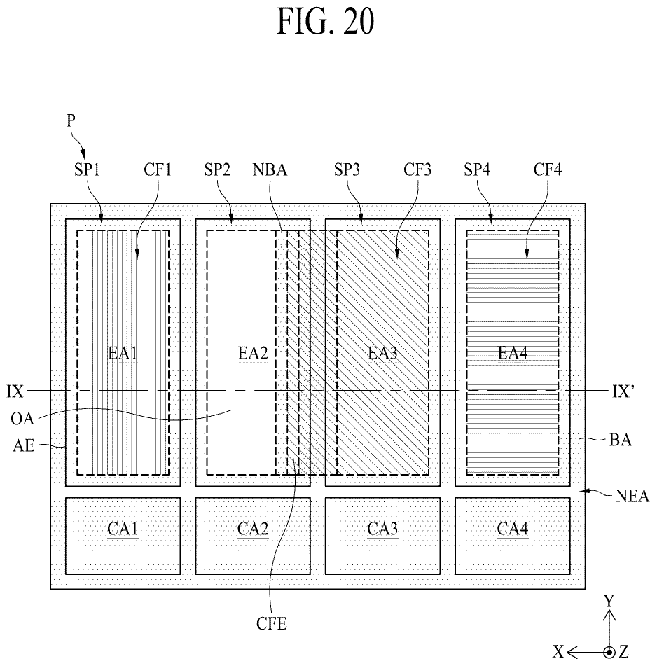

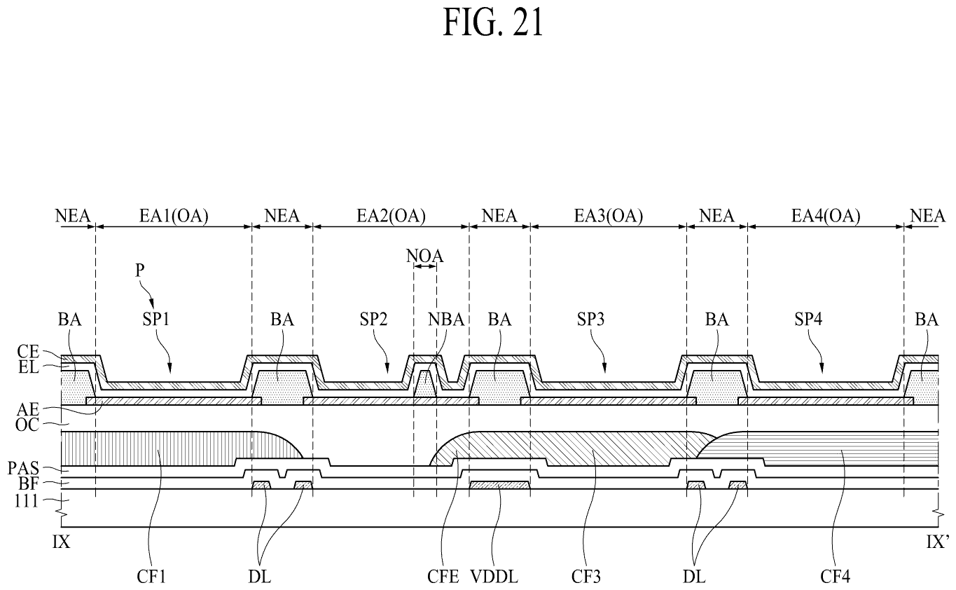

FIG. 20 illustrates a bank portion and a color filter of a pixel according to another example embodiment of the present disclosure. FIG. 21 is a cross-sectional view taken along line IX-IX′ in FIG. 20 according to another example embodiment of the present disclosure. FIGS. 20 and 21 illustrate embodiments of the present disclosure in which a configuration of the bank portion and the color filter is modified in the light emitting display apparatus described with reference to FIGS. 1 to 19. In the following description referring to FIGS. 20 and 21, the same reference numerals will be used for the same components, except for the modified configurations, and their redundant descriptions will be omitted or briefly described.

As shown in FIGS. 20 and 21, the second subpixel SP2 of the light emitting display apparatus according to another embodiment of the present disclosure may further include a sub non-opening bank portion NBA that is spaced apart from an adjacent bank portion BA in a first direction and extends in a second direction.

The sub non-opening bank portion NBA may be disposed in the second subpixel SP2, and not in the first, third, and fourth subpixels SP1, SP3 and SP4. For example, the sub non-opening bank portion NBA may be disposed on the pixel electrode AE of the second subpixel SP2, and may define the non-opening area NOA of the pixel electrode AE of the second subpixel SP2 that is spaced apart by a certain distance from the bank portion BA between the second subpixel SP2 and the third subpixel SP3 in the second direction (or Y-axis direction) and extends in the second direction. As a result, the emission area EA2 of the second subpixel SP2 may have a smaller area than the emission areas EA1, EA3 and EA4 of the first subpixel SP1, the third subpixel SP3, and the fourth subpixel SP4.

The third color filter CF3 of the third subpixel SP3 adjacent to the second subpixel SP2 may be extended in a first direction and be disposed to overlap an opening area OA of the pixel electrode AE of the second subpixel SP2. The sub non-opening bank portion NBA of the second subpixel SP2 may be disposed to overlap the color filter extension portion CFE extended from the third color filter CF3. For example, the color filter extension portion CFE may be formed by being extended from the color filter CF3 of the third subpixel SP3, and may be configured to overlap a right edge of the pixel electrode AE of the second subpixel SP2 and the sub non-opening bank portion NBA. For example, the color filter extension portion CFE may be configured such that the second subpixel SP2 has a reflectance equal to or lower than that of the other subpixels SP1, SP3 and SP4. According to another embodiment of the present disclosure, the color filter extension portion CFE having a lower reflectance than that of the second subpixel SP2 may be disposed at the emission area EA2 of the second subpixel SP2. As a result, the influence of line width variations and process deviations of the color filter extension portion CFE may be minimized, thereby optimizing the average reflectance of the second subpixel SP2 and, accordingly, improving the reflectance non-uniformity ratio caused by process deviations.

According to another embodiment of the present disclosure, the sub non-opening bank portion NBA of the second subpixel SP2 may define the non-opening area NOA of the pixel electrode AE of the second subpixel SP2 extending in the second direction (or Y-axis direction) within the emission area EA2 of the second subpixel SP2. The color filter extension portion CFE having a lower reflectance than that of the second subpixel SP2 may be disposed in the emission area EA2 of the second subpixel SP2, and the color filter extension portion CFE may be disposed to overlap a right edge of the pixel electrode AE of the second subpixel SP2 and the sub non-opening bank portion NBA. As a result, while minimizing additional mask processes, the aperture ratios of the emission areas EA1, EA2, EA3 and EA4 may be optimized, the average reflectance of the second subpixel SP2 may be optimized, and accordingly, the reflectance variation ratio caused by process deviations may be improved. Accordingly, the light emitting display apparatus according to another embodiment of the present disclosure may reduce the increased reflectance caused by the absence of a polarizer, improve the reflectance variation ratio, enhance light efficiency, and improve reflective color and visual perception.

A light emitting display apparatus according to one or more example embodiments of the present disclosure will be described below.

A light emitting display apparatus according to one or more embodiments of the present disclosure may include a substrate including a plurality of subpixels arranged in a first direction, each of the plurality of subpixels including an emission area and a non-emission area, at least one thin film transistor disposed in the non-emission area on the substrate, at least one protective layer disposed on the at least one thin film transistor, and at least one color filter disposed on the at least one protective layer in at least some of the plurality of subpixels, each of the plurality of subpixels may include a pixel electrode, an emission layer, a common electrode, and a bank portion defining an opening area of the pixel electrode, and at least one subpixel among the plurality of subpixels may be disposed such that at least a portion of a color filter of at least one other subpixel, which is adjacent to the at least one subpixel, extends in the first direction and overlaps the opening area of the pixel electrode of the at least one subpixel.

According to one or more embodiments of the present disclosure, the bank portion may include at least one of a light absorbing material and a black material.

According to one or more embodiments of the present disclosure, the at least one subpixel may be a white subpixel in which the at least one color filter is not disposed, and an extended portion of the color filter of the at least one other subpixel may be disposed to overlap the opening area of the pixel electrode of the at least one subpixel.

According to one or more embodiments of the present disclosure, the extended portion of the color filter may be disposed to overlap a central portion of the opening area of the pixel electrode in a second direction intersecting the first direction.

According to one or more embodiments of the present disclosure, the extended portion of the color filter may be configured such that the at least one subpixel has the same or lower reflectance than the at least one other subpixel.

According to one or more embodiments of the present disclosure, the extended portion of the color filter may be configured to reduce a reflectance non-uniformity ratio of the at least one subpixel.

According to one or more embodiments of the present disclosure, the at least one other subpixel may include at least one of a red subpixel and a blue subpixel.

According to one or more embodiments of the present disclosure, each of the plurality of subpixels may further include a non-opening bank portion configured such that at least a portion of the bank portion extends in the first direction to define a non-opening area of the pixel electrode.

According to one or more embodiments of the present disclosure, the non-opening bank portion may be disposed between the pixel electrode and the emission layer.

According to one or more embodiments of the present disclosure, the non-opening bank portion may be disposed in parallel in the first direction with respect to the plurality of subpixels.

According to one or more embodiments of the present disclosure, the non-opening bank portion may be disposed to overlap a central portion of the pixel electrode in a second direction intersecting the first direction.

According to one or more embodiments of the present disclosure, the at least one subpixel may be a white subpixel in which the at least one color filter is not disposed, and the non-opening bank portion of the at least one subpixel may be disposed to overlap at least a portion of an extended portion of the color filter of the at least one other subpixel.

According to one or more embodiments of the present disclosure, the non-opening bank portion of the at least one subpixel may include a first sub non-opening bank portion and a second sub non-opening bank portion, which are spaced apart from each other in a second direction intersecting the first direction, with the extended portion of the color filter therebetween.

According to one or more embodiments of the present disclosure, the first sub non-opening bank portion may be disposed to overlap one side of the extended portion of the color filter in the second direction, and the second sub non-opening bank portion may be disposed to overlap the other side of the extended portion of the color filter in the second direction.

According to one or more embodiments of the present disclosure, the non-opening bank portion of each of the plurality of subpixels may include a first sub non-opening bank portion and a second sub non-opening bank portion, which are spaced apart from each other in a second direction intersecting the first direction, with a central portion of the pixel electrode therebetween.

According to one or more embodiments of the present disclosure, the first sub non-opening bank portion and the second sub non-opening bank portion may be disposed in parallel with each other in the first direction.

According to one or more embodiments of the present disclosure, the extended portion of the color filter of the at least one other subpixel may be disposed between the first sub non-opening bank portion and the second sub non-opening bank portion.

According to one or more embodiments of the present disclosure, the non-opening bank portion of the at least one subpixel may be disposed to overlap a central portion of the extended portion of the color filter in a second direction intersecting the first direction.

According to one or more embodiments of the present disclosure, the bank portion disposed between the plurality of subpixels may extend toward a central portion of the pixel electrode in the first direction and may be configured to define a non-opening area of the pixel electrode.

According to one or more embodiments of the present disclosure, the at least one subpixel may be a white subpixel in which the at least one color filter is not disposed, and an extended portion of the color filter of the at least one other subpixel may be disposed to overlap both the non-opening area and the opening area of the pixel electrode of the at least one subpixel.

According to one or more embodiments of the present disclosure, the at least one subpixel may further include a sub non-opening bank portion extending in a second direction intersecting the first direction, the sub non-opening bank portion being spaced apart from an adjacent bank portion in the first direction.

According to one or more embodiments of the present disclosure, the sub non-opening bank portion may be disposed to overlap the extended portion of the color filter.

According to one or more embodiments of the present disclosure, the light emitting display apparatus may further include a transmittance control film disposed on a rear surface of the substrate.

According to one or more embodiments of the present disclosure, the transmittance control film may include at least one of a transparent film and a light absorbing film.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the light emitting display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A light emitting display apparatus, comprising:
a substrate including a plurality of subpixels arranged in a first direction, each of the plurality of subpixels including an emission area and a non-emission area;
at least one thin film transistor disposed in the non-emission area on the substrate;
at least one protective layer disposed on the at least one thin film transistor; and
at least one color filter disposed on the at least one protective layer in at least some of the plurality of subpixels,
wherein each of the plurality of subpixels includes a pixel electrode, an emission layer, a common electrode, and a bank portion defining an opening area of the pixel electrode, and
wherein at least one subpixel among the plurality of subpixels is disposed such that at least a portion of a color filter of at least one other subpixel, which is adjacent to the at least one subpixel, extends in the first direction and overlaps the opening area of the pixel electrode of the at least one subpixel.

2. The light emitting display apparatus of claim 1, wherein the bank portion includes at least one of a light absorbing material and a black material.

3. The light emitting display apparatus of claim 1, wherein the at least one subpixel is a white subpixel in which the at least one color filter is not disposed, and
wherein an extended portion of the color filter of the at least one other subpixel is disposed to overlap the opening area of the pixel electrode of the at least one subpixel.

4. The light emitting display apparatus of claim 3, wherein the extended portion of the color filter is disposed to overlap a central portion of the opening area of the pixel electrode in a second direction intersecting the first direction.

5. The light emitting display apparatus of claim 3, wherein the extended portion of the color filter is configured such that the at least one subpixel has the same or lower reflectance than the at least one other subpixel.

6. The light emitting display apparatus of claim 3, wherein the extended portion of the color filter is configured to reduce a reflectance non-uniformity ratio of the at least one subpixel.

7. The light emitting display apparatus of claim 3, wherein the at least one other subpixel includes at least one of a red subpixel and a blue subpixel.

8. The light emitting display apparatus of claim 1, wherein each of the plurality of subpixels further includes a non-opening bank portion configured such that at least a portion of the bank portion extends in the first direction to define a non-opening area of the pixel electrode.

9. The light emitting display apparatus of claim 8, wherein the non-opening bank portion is disposed between the pixel electrode and the emission layer.

10. The light emitting display apparatus of claim 8, wherein the non-opening bank portion is disposed in parallel in the first direction with respect to the plurality of subpixels.

11. The light emitting display apparatus of claim 10, wherein the non-opening bank portion is disposed to overlap a central portion of the pixel electrode in a second direction intersecting the first direction.

12. The light emitting display apparatus of claim 8, wherein the at least one subpixel is a white subpixel in which the at least one color filter is not disposed, and
wherein the non-opening bank portion of the at least one subpixel is disposed to overlap at least a portion of an extended portion of the color filter of the at least one other subpixel.

13. The light emitting display apparatus of claim 12, wherein the non-opening bank portion of the at least one subpixel includes a first sub non-opening bank portion and a second sub non-opening bank portion, which are spaced apart from each other in a second direction intersecting the first direction, with the extended portion of the color filter therebetween.

14. The light emitting display apparatus of claim 13, wherein the first sub non-opening bank portion is disposed to overlap one side of the extended portion of the color filter in the second direction, and
wherein the second sub non-opening bank portion is disposed to overlap the other side of the extended portion of the color filter in the second direction.

15. The light emitting display apparatus of claim 8, wherein the non-opening bank portion of each of the plurality of subpixels includes a first sub non-opening bank portion and a second sub non-opening bank portion, which are spaced apart from each other in a second direction intersecting the first direction, with a central portion of the pixel electrode therebetween.

16. The light emitting display apparatus of claim 15, wherein the first sub non-opening bank portion and the second sub non-opening bank portion are disposed in parallel with each other in the first direction.

17. The light emitting display apparatus of claim 16, wherein the extended portion of the color filter of the at least one other subpixel is disposed between the first sub non-opening bank portion and the second sub non-opening bank portion.

18. The light emitting display apparatus of claim 12, wherein the non-opening bank portion of the at least one subpixel is disposed to overlap a central portion of the extended portion of the color filter in a second direction intersecting the first direction.

19. The light emitting display apparatus of claim 1, wherein the bank portion disposed between the plurality of subpixels extends toward a central portion of the pixel electrode in the first direction and is configured to define a non-opening area of the pixel electrode.

20. The light emitting display apparatus of claim 19, wherein the at least one subpixel is a white subpixel in which the at least one color filter is not disposed, and
wherein an extended portion of the color filter of the at least one other subpixel is disposed to overlap both the non-opening area and the opening area of the pixel electrode of the at least one subpixel.

21. The light emitting display apparatus of claim 20, wherein the at least one subpixel further includes a sub non-opening bank portion extending in a second direction intersecting the first direction, the sub non-opening bank portion being spaced apart from an adjacent bank portion in the first direction.

22. The light emitting display apparatus of claim 21, wherein the sub non-opening bank portion is disposed to overlap the extended portion of the color filter.

23. The light emitting display apparatus of claim 1, further comprising a transmittance control film disposed on a rear surface of the substrate.

24. The light emitting display apparatus of claim 23, wherein the transmittance control film includes at least one of a transparent film and a light absorbing film.
